(19) United States
(12) Patent Application Publication
(10) Pub. No.: US 2026/0319363 A1
(43) Pub. Date: Oct. 15, 2026

(54) PHOTOSENSITIVE RESIN COMPOSITION AND CURABLE FILM

(71) Applicant: Daxin Materials Corporation, Taichung City (TW)

(72) Inventors: Tzu-Yu CHEN, Taichung City (TW); Tse-Hsueh LIN, Taichung City (TW); Ching-Tien LEE, Taichung City (TW)

(21) Appl. No.: 19/352,460

(22) Filed: Oct. 8, 2025

(30) Foreign Application Priority Data
Apr. 2, 2025 (TW) 114112822

(51) Int. Cl. G03F 7/038; C08G 69/26

(52) U.S. Cl. CPC G03F 7/0387; C08G 69/26; G03F 7/0388

(57) ABSTRACT

A photosensitive resin composition includes a polymer. The polymer has a plurality of repeating units represented by formula (I) and a plurality of repeating units represented by formula (II). Formula (I) and formula (II) are defined as in the specification. A curable film is formed by curing the photosensitive resin composition.

### RELATED APPLICATIONS

This application claims priority to Taiwan Application Serial Number 114112822, filed Apr. 2, 2025, which is herein incorporated by reference.

### BACKGROUND

### Technical Field

The present disclosure relates to a resin composition and a curable film. More particularly, the present disclosure relates to a photosensitive resin composition that can obtain the good material properties at the low curing temperature and a curable film.

### Description of Related Art

Polyimide is a polymer material with an imide structure, which has the good thermal stability, the mechanical properties, the electrical properties, the low hygroscopicity and the chemical stability. Therefore, polyimide is one of the important high-performance polymer materials in today's semiconductor manufacturing process.

Conventional polyimide precursor requires a high-temperature curing process to obtain the polyimide polymer. The curing temperature must be reached to 230° C. to 350° C. to ensure that the polyimide has the high glass transition temperature and the good mechanical properties and chemical resistance. However, the high-temperature curing easily leads the residual stress on the substrate carried polyimide, causing the substrate to warp, resulting in the excessive energy consumption and increasing the manufacturing cost.

### SUMMARY

According to one aspect of the present disclosure, a photosensitive resin composition is provided. The photosensitive resin composition includes a polymer, which has a plurality of repeating units represented by formula (I) and a plurality of repeating units represented by formula (II):

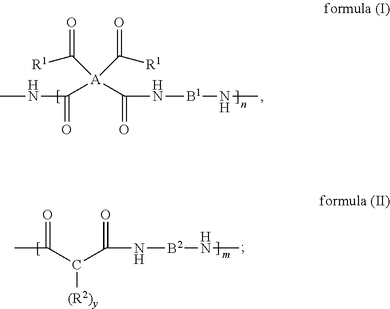

wherein A is a tetravalent organic group of 6 to 40 carbon atoms, B¹ and B² are each independently a divalent organic group of 6 to 40 carbon atoms, C is a trivalent organic group to a hexavalent organic group of 6 to 40 carbon atoms, R¹ is a photosensitive crosslinking group, and R² has a structure represented by formula (II-a) or formula (II-b):

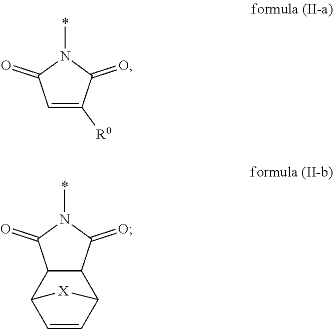

wherein R⁰ is a hydrogen atom or a methyl group, and X is a methylene group, an oxygen atom or a sulfur atom. n is an integer greater than or equal to 1, m is an integer greater than or equal to 1, and y is an integer from 1 to 3. When X is the methylene group, the following condition is satisfied: 0.1≤a molar ratio of the repeating units represented by formula (II) to all repeating units of the polymer≤0.4.

According to another aspect of the present disclosure, a photosensitive resin composition is provided. The photosensitive resin composition includes a thermal base generator and a polymer. The polymer has a plurality of repeating units represented by formula (I) and a plurality of repeating units represented by formula (II):

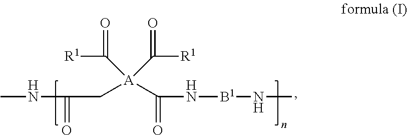

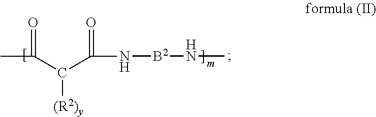

wherein A is a tetravalent organic group of 6 to 40 carbon atoms, B¹ and B² are each independently a divalent organic group of 6 to 40 carbon atoms, C is a trivalent organic group to a hexavalent organic group of 6 to 40 carbon atoms, R¹ is a photosensitive crosslinking group, and R² has a structure represented by formula (II-a) or formula (II-b):

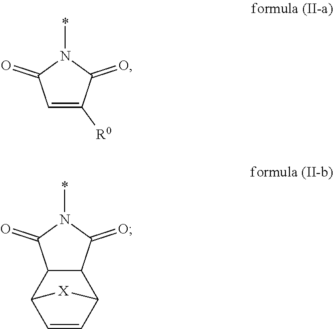

wherein R⁰ is a hydrogen atom or a methyl group, and X is a methylene group, an oxygen atom or a sulfur atom. n is an integer greater than or equal to 1, m is an integer greater than or equal to 1, and y is an integer from 1 to 3.

According to further another aspect of the present disclosure, a curable film is provided. The curable film is formed by curing the photosensitive resin composition according to the foregoing aspect. The repeating units represented by formula (I) in the photosensitive resin composition undergo a cyclization reaction to form a plurality of repeating units represented by formula (1-1):

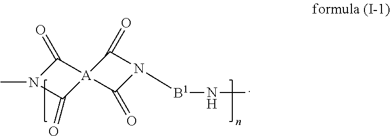

### DETAILED DESCRIPTION

The present disclosure will be further exemplified by the following specific embodiments. However, the embodiments can be applied to various inventive concepts and can be embodied in various specific ranges. The specific embodiments are only for the purposes of description, and are not limited to these practical details thereof.

In the present disclosure, the compound structure can be represented by a skeleton formula, and the representation can omit the carbon atom, the hydrogen atom and the carbon-hydrogen bond. In the case that the functional group is depicted clearly in the structural formula, the depicted one is preferred.

A photosensitive resin composition is provided according to one aspect of the present disclosure, which includes a polymer. The polymer has a plurality of repeating units represented by formula (I) and a plurality of repeating units represented by formula (II):

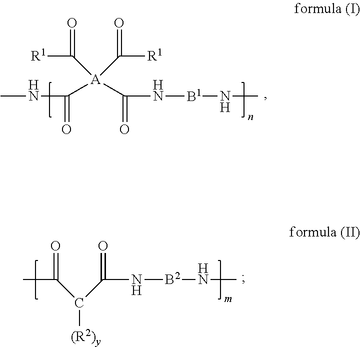

wherein A is a tetravalent organic group of 6 to 40 carbon atoms, B¹ and B² are each independently a divalent organic group of 6 to 40 carbon atoms, C is a trivalent organic group to a hexavalent organic group of 6 to 40 carbon atoms, R¹ is a photosensitive crosslinking group, and R² has a structure represented by formula (II-a) or formula (II-b):

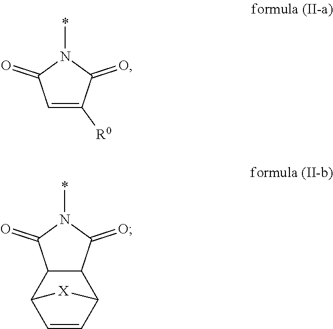

wherein R⁰ is a hydrogen atom or a methyl group, and X is a methylene group, an oxygen atom or a sulfur atom. n is an integer greater than or equal to 1, m is an integer greater than or equal to 1, and y is an integer from 1 to 3. When X is the methylene group, the following condition is satisfied: 0.1≤a molar ratio of the repeating units represented by formula (II) to all repeating units of the polymer≤0.4. Furthermore, when the condition of 0.1≤a molar ratio of the repeating units represented by formula (II) to all repeating units of the polymer≤0.4 is satisfied, it is significantly for improving the thermal property of the photosensitive resin composition, such as the efficacies of storage modulus (E′) or glass transition temperature (T_{g}), and after the exposure, the crosslinking is more easily performed to generate the development contrast.

Specifically, the plurality of repeating units represented by formula (I) are formed by the reaction of a dianhydride compound and a diamine compound, and the plurality of repeating units represented by formula (II) are formed by the reaction of a diacid compound and a diamine compound, wherein the dianhydride compound can include a plurality of dianhydride monomers. The dianhydride monomer can include at least one of an aromatic dianhydride and an alicyclic dianhydride. The aromatic dianhydride can be at least one selected from a group consisting of formula (a), formula (b), formula (c), formula (d), formula (e) and formula (f):

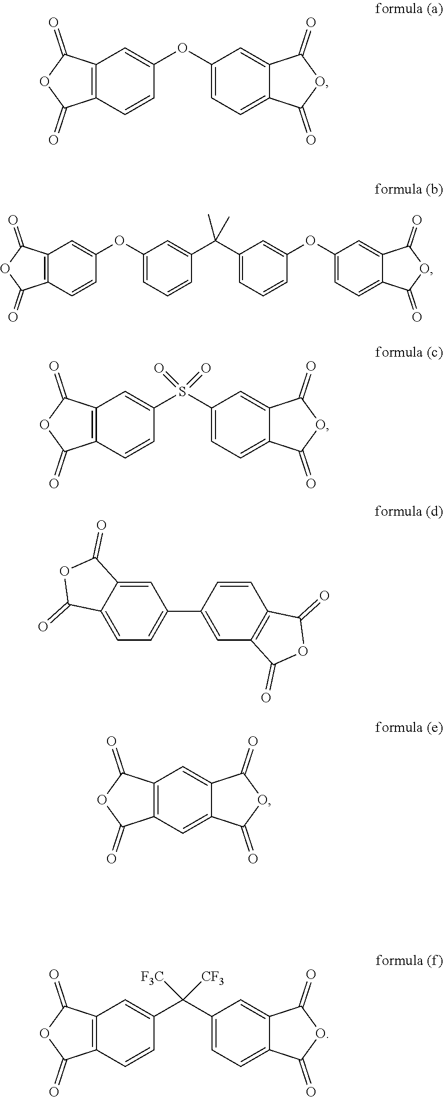

The alicyclic dianhydride can be at least one selected from a group consisting of formula (g), formula (h) and formula (i):

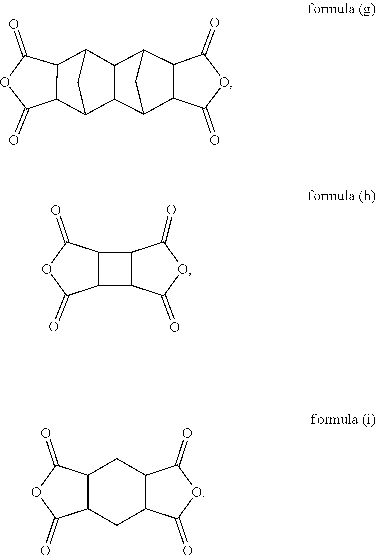 [SMILES: O=C1OC(=O)C2C3CC(C12)C1C2CC(C4C(=O)OC(=O)C24)C31 ; O=C1OC(=O)C2C1C1C(=O)OC(=O)C21 ; O=C1OC(=O)C2CC3C(=O)OC(=O)C3CC12]

It is favorable for improving the mechanical properties of the subsequently prepared curable film by using the aromatic dianhydride. It is favorable for improving the electrical properties of the curable film by using the alicyclic dianhydride.

The diamine compound can include a plurality of diamine monomers, and the diamine monomer can include at least one of an aromatic diamine and an alicyclic diamine. The aromatic diamine can be at least one selected from a group consisting of formula (j), formula (k), formula (I), formula (m), formula (n), formula (o), formula (p), formula (q), formula (r), formula(s), formula (t), formula (u), formula (v) and formula (w):

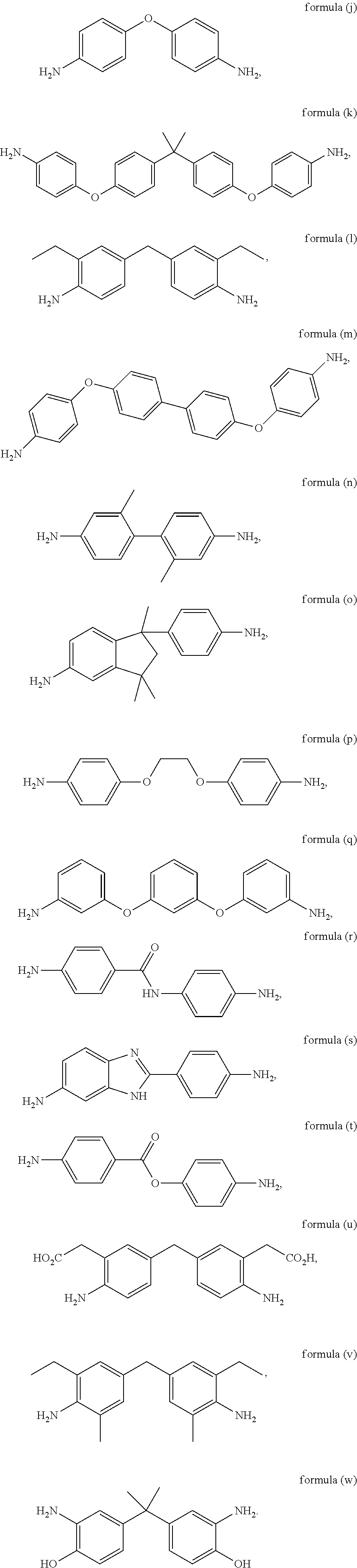

The alicyclic diamine can be a structure represented by formula (x):

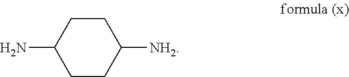

A photosensitive resin composition is provided according to another aspect of the present disclosure, which includes a thermal base generator and a polymer. The polymer has a plurality of repeating units represented by formula (I) and a plurality of repeating units represented by formula (II):

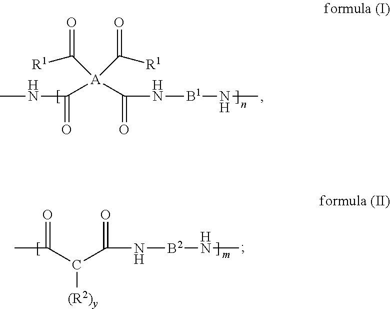

wherein A is a tetravalent organic group of 6 to 40 carbon atoms, B¹ and B² are each independently a divalent organic group of 6 to 40 carbon atoms, C is a trivalent organic group to a hexavalent organic group of 6 to 40 carbon atoms, R¹ is a photosensitive crosslinking group, and R² has a structure represented by formula (II-a) or formula (II-b):

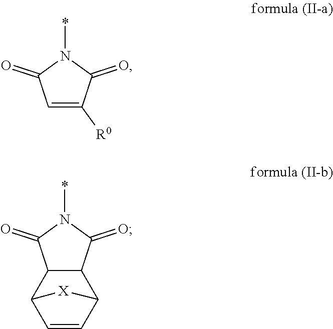

wherein R⁰ is a hydrogen atom or a methyl group, and X is a methylene group, an oxygen atom or a sulfur atom. n is an integer greater than or equal to 1, m is an integer greater than or equal to 1, and y is an integer from 1 to 3.

In further another aspect of the present disclosure, the repeating unit represented by formula (I) in the polymer can independently form a first polymer, and the repeating unit represented by formula (II) in the polymer can independently form a second polymer, that is, the polymer can be a polymer blend which includes the first polymer and the second polymer. Alternatively, the repeating unit represented by formula (I) and the repeating unit represented by formula (II) in the polymer can form a copolymer, and the copolymer can be combined in the form of a random copolymer or a block copolymer.

Accordingly, since the polymer in the photosensitive resin composition of the present disclosure has the structure represented by formula (II-a) or formula (II-b), it is favorable for the rearrangement and crosslinking reaction of polymer and increases the crosslinking density of the polymer chain of polymer, so that the higher glass transition temperature can be obtained at the low curing temperature and the product after curing also can have the good thermal properties (such as storage modulus or level of weight loss) and the mechanical properties. On the other hand, the high cyclization rate and the good chemical resistance can be maintained at the low temperature process (≤200° C.) by adding the thermal base generator. Furthermore, the photosensitive crosslinking group in the polymer provides the photosensitivity, so it can be patterned by the exposure and development. Thus, the photosensitive resin composition can simultaneously have the properties of the insulating material and the photoresist material, which is favorable for reducing the process steps, reducing the costs and improving the yield.

Further, A can be the tetravalent organic group including 1 to 4 benzene rings, B¹ and B² can be each independently the divalent organic group including 1 to 4 benzene rings, and C can be the trivalent organic group to the hexavalent organic group including 1 to 4 benzene rings. The benzene rings of at least one of A, B¹, B² and C can have at least one linking group therebetween, and the linking group can be a divalent organic group of 1 to 6 carbon atoms. The linking group can include at least one selected from a group consisting of an oxygen atom, a nitrogen atom, a sulfur atom, an alkenyl group, an alkynyl group, an ester group, an ether group, and a ketone group.

Further, R¹ can have a structure represented by formula (III):

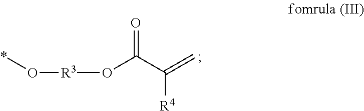

wherein R³ can be an alkylene group of 1 to 8 carbon atoms, and R⁴ can be a hydrogen atom or an alkyl group of 1 to 3 carbon atoms.

Further, n can be an integer from 1 to 150, and m can be an integer from 1 to 150.

Further, the weight average molecular weight (Mw) of the polymer can be 10000 to 50000, preferably can be 20000 to 40000. It is favorable for the pattern formation by controlling the weight average molecular weight of the polymer.

Further, the photosensitive resin composition can further include a thermal crosslinking agent, which is favorable for promoting the crosslinking reaction during the curing of the photosensitive resin composition and improving the properties of the product after curing. The thermal crosslinking agent can have a thermally reactive functional group, and the thermally reactive functional group can be at least one selected from a group consisting of a hydroxymethyl group (—CH₂OH), an alkoxymethyl group (—CH₂OR), an oxiranyl group, an isocyanate group, a bismaleimide group, an alkenyl group and an alkynyl group, wherein R can be an alkyl group, preferably can be the alkyl group of 1 to 3 carbon atoms, but it is not limited thereto. A proportion of the thermal crosslinking agent in the photosensitive resin composition can be 0.1% to 20%. Preferably, the proportion of the thermal crosslinking agent in the photosensitive resin composition can be 0.1% to 10%. More preferably, the proportion of the thermal crosslinking agent in the photosensitive resin composition can be 3% to 5%. Moreover, a crosslinking temperature of the thermal crosslinking agent can be 120° C. to 170° C.

The photosensitive resin composition can further include at least one of a photoinitiator and a multifunctional acrylic photocrosslinker, which is favorable for promoting the photocuring reaction of the photosensitive resin composition. The photoinitiator can be at least one selected from a group consisting of an acylphosphine oxide compound, a transition metal compound, an oxime compound, a benzophenone derivative, an α-hydroxy ketone compound and an α-aminoalkyl phenyl ketone compound. A proportion of the photoinitiator in the photosensitive resin composition can be 0.1% to 5%.

The thermal base generator can generate an alkaline substance when heating in the low temperature process to promote the ring-closing reaction of the photosensitive resin composition. The thermal base generator is provided according to further another aspect of the present disclosure can have at least one of a structure represented by formula (IV) and a structure represented by formula (V):

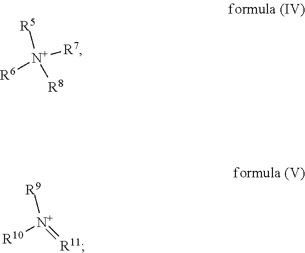

Wherein R⁵, R⁶, R⁷, R⁸, R⁹ and R¹⁰ can be each independently a hydrogen atom, an aromatic ring group or an alkyl group, and R¹¹ can be an alkylene group. Further, at least one of R⁵, R⁶, R⁷, R⁸, R⁹, R¹⁰ and R¹¹ can be substituted by at least one selected from a group consisting of an oxygen atom, a nitrogen atom, a sulfur atom, an alkenyl group, an alkynyl group, an ether group and a ketone group. Further, at least one of R⁵ and R⁶, R⁷ and R⁸, R⁹ and R¹⁰, R⁹ and R¹¹ can be bonded to form a cyclic structure.

Further, a proportion of the thermal base generator in the photosensitive resin composition can be 0.1% to 5%. Preferably, the proportion of the thermal base generator in the photosensitive resin composition can be 0.1% to 1%. A decomposition temperature of the alkaline substance generated by the thermal base generator can be 100° C. to 170° C., and the acid dissociation constant (pKa) of the conjugate acid of the alkaline substance can greater than 5.

Further, the alkaline substance generated by the thermal base generator can be an organic base, and can be a primary amine, a secondary amine, a tertiary amine, an amidine or a guanidine. Further, the thermal base generator can be an ionic thermal base generator, which includes a cation and an anion. The cation can be selected from a group consisting of the primary amine, the secondary amine, the tertiary amine, the amidine and the guanidine. The anion can include an organic acid anion or an inorganic acid anion; or the anion can be selected from a group consisting of a carboxylate, a sulfate, a phosphate and a phenol.

In further another aspect of the present disclosure, the photosensitive resin composition can further include a photopolymerizable monomer to enhance the photosensitivity of the photosensitive resin composition. The photopolymerizable monomer can have an unsaturated double bond, and can have two or more unsaturated double bonds. Further, the photopolymerizable monomer can include an acrylic compound, and can be selected from a group consisting of an ethylene glycol dimethacrylate, a pentaerythritol diacrylate, and a dipentaerythritol hexaacrylate. Further, a proportion of the photopolymerizable monomer in the photosensitive resin composition can be 1% to 30%.

In further another aspect of the present disclosure, the photosensitive resin composition can further include a solvent, which can be but is not limited to Y-butyrolactone, N-methylpyrrolidone, dimethylsulfoxide, N-ethylpyrrolidone, dimethylformamide, or dimethylacetamide. Further, a proportion of the solvent in the photosensitive resin composition can be 30% to 80%.

In further another aspect of the present disclosure, the photosensitive resin composition can further include other additives, such as at least one of a leveling agent, a heterogeneous interface promoter, a sensitizer and an antioxidant, to enhance the processability, stability, and product properties thereof of the photosensitive resin composition.

A curable film is provided according to further another aspect of the present disclosure, which is formed by curing the abovementioned photosensitive resin composition. The repeating units represented by formula (I) in the photosensitive resin composition undergo a cyclization reaction to form a plurality of repeating units represented by formula (1-1):

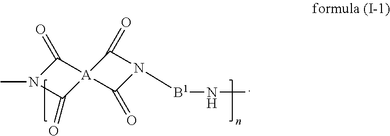

Further, a cyclization rate of the curable film can be greater than 80%, so that the abovementioned photosensitive resin composition can have the great cyclization property during the curing process.

The present disclosure will be further exemplified by the following specific embodiments so as to facilitate utilizing and practicing the present disclosure completely by the people skilled in the art without over-interpreting and over-experimenting. However, the readers should understand that the present disclosure should not be limited to these practical details thereof, that is, these practical details are used to describe how to implement the materials and methods of the present disclosure and are not necessary.

### Synthesis Example

Synthesis Example 1: ODPA (55 mmol; 17.1 g), PMDA (30 mmol; 6.5 g), HEMA (170 mmol; 22.1 g), pyridine (170 mmol, 13.5 g) and GBL (200 g) are added in 1 L of three-necked flask to form a mixture. The mixture is heated to 60° C. and stirred for 2 hours, then cooled in the ice bath. Afterward, the diacid compound represented by formula (II-b-1) (15 mmol; 4.9 g) is added to the mixture, DCC solution (200 mmol; 41.2 g of DCC dissolved in 50 g of GBL), mMEA solution (30.3 mmol; 8.5 g of mMEA dissolved in 100 g of GBL) and m-tolidine solution (70.7 mmol; 15 g of m-tolidine dissolved in 100 g of GBL) are added dropwise in sequence via the feeding tube to obtain a reaction mixture. The obtained reaction mixture is stirred in the ice bath for 18 hours and filtered to remove the generated precipitate to obtain the obtained reaction solution, and then the obtained reaction solution is dripped into 4 L of water. Then, the generated solid is filtered, separated and vacuum dried to obtain the polymer of Synthesis Example 1. The polymer of Synthesis Example 1 is calculated, a molar ratio of the repeating unit represented by formula (II) to all repeating units in the polymer is 0.15.

The weight average molecular weight of the polymer can be measured by gel permeation chromatography (GPC), and uses the standard polystyrene as calibration conversion. The weight average molecular weight of the polymer of Synthesis Example 1 is 28500.

Further, the reactant of Synthesis Example 1 can perform the chemical reaction shown in formula (A) to obtain the polymer of Synthesis Example 1:

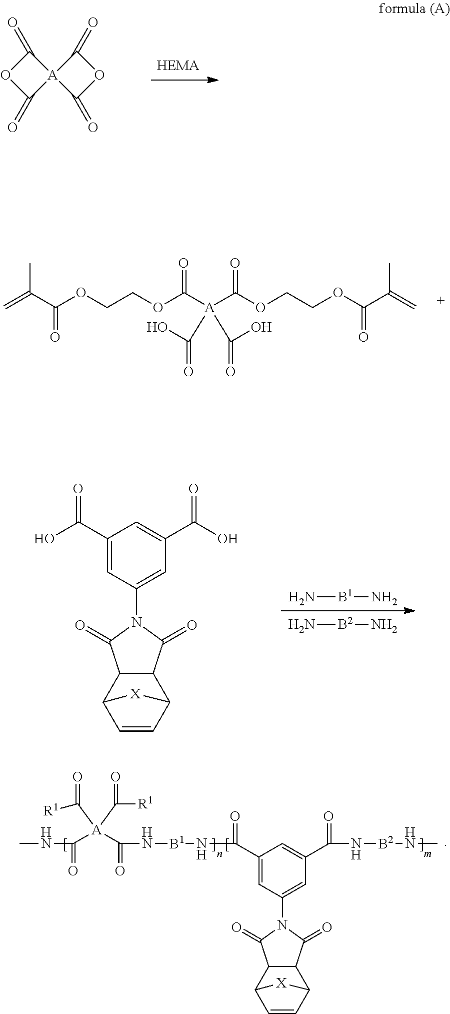

Specifically, the diacid compound represented by formula (II-b-1) is prepared by the following steps: 5-aminoisophalic acid (450 mmol; 81.5 g), nadic anhydride (450 mmol; 73.8 g) and N,N-dimethyl formamide (DMF; 450 mL) are added in 1 L of three-necked flask to form a mixture. The mixture is stirred for 18 hours at the room temperature, and then sodium acetate (135 mmol; 11.1 g) and acetic anhydride (1.5 mmol; 153 g) are added in the mixture. The mixture is stirred at 60° C. for 2 hours, the mixture is cooled to the room temperature and poured into 2 L of dilute hydrochloric (1M). The generated solid is filtered, separated and vacuum dried, that is the diacid compound represented by formula (II-b-1).

It should be noted that the groups of A, X, B¹, B² and R¹ in the formula (A) can have different chemical structures depending on the different reactants. For example, the dianhydride compound used in Synthesis Example 1 includes ODPA and PMDA, so that the A group in formula (A) can be the aromatic group in ODPA or PMDA. Furthermore, the diamine compound used in Synthesis Example 1 is mMEA and m-tolidine, so that H₂N—B¹—N₂H in formula (A) can be mMEA or m-tolidine, and H₂N—B²—N₂H in formula (A) can be mMEA or m-tolidine. That is, in the polymer structure represented by formula (A), the groups of A, B¹ and B² are not limited to a specific structure, and they can be any combination of the used dianhydride compound and diamine compound. Further, the reaction mechanisms of the subsequent Synthesis Examples and Comparative Synthesis Examples are the same or similar to those of Synthesis Example 1, and will not be further described herein.

Synthesis Example 2: the synthesis steps of the polymer of Synthesis Example 2 are the same as those of Synthesis Example 1, except that the reactants used in Synthesis Example 2 is ODPA (40 mmol; 12.4 g), PMDA (30 mmol; 6.5 g), HEMA (140 mmol; 18.2 g), pyridine (140 mmol; 11.1 g), GBL (200 g), the diacid compound represented by formula (II-b-1) (30 mmol; 9.8 g), DCC solution (200 mmol; 41.2 g of DCC dissolved in 50 g of GBL), mMEA solution (10 mmol; 2.8 g of mMEA dissolved in 50 g of GBL) and m-tolidine solution (91 mmol; 19.3 g of m-tolidine dissolved in 150 g of GBL). The weight average molecular weight of the polymer of Synthesis Example 2 is 21100, wherein the polymer of Synthesis Example 2 is calculated, a molar ratio of the repeating unit represented by formula (II) to all repeating units in the polymer is 0.30.

Synthesis Example 3: the synthesis steps of the polymer of Synthesis Example 3 are the same as those of Synthesis Example 1, except that the reactants used in Synthesis Example 3 is ODPA (50 mmol; 15.5 g), PMDA (30 mmol; 6.5 g), HEMA (160 mmol; 20.8 g), pyridine (160 mmol; 12.7 g), GBL (200 g), DCC solution (200 mmol; 41.2 g of DCC dissolved in 50 g of GBL) and m-tolidine solution (101 mmol; 21.4 g of m-tolidine dissolved in 200 g of GBL). In Synthesis Example 3, mMEA solution is not used, and the diacid compound represented by formula (II-b-1) is replaced with the diacid compound represented by formula (II-b-2) (20 mmol; 6.6 g). The weight average molecular weight of the polymer of Synthesis Example 3 is 23100, wherein the polymer of Synthesis Example 3 is calculated, a molar ratio of the repeating unit represented by formula (II) to all repeating units in the polymer is 0.20.

The preparation method of the diacid compound represented by formula (II-b-2) is similar to that of the diacid compound represented by formula (II-b-1), expect that nadic anhydride is replaced with 3,6-oxo-1,2,3,6-tetrahydrophthalic anhydride.

Synthesis Example 4: the synthesis steps of the polymer of Synthesis Example 4 are the same as those of Synthesis Example 1, except that the reactants used in Synthesis Example 4 is ODPA (40 mmol; 12.4 g), PMDA (30 mmol; 6.5 g), HEMA (140 mmol; 18.2 g), pyridine (140 mmol; 11.1 g), GBL (200 g), DCC solution (200 mmol; 41.2 g of DCC dissolved in 50 g of GBL) and m-tolidine solution (81 mmol; 17.2 g of m-tolidine dissolved in 150 g of GBL). In Synthesis Example 4, mMEA solution is replaced with ODA solution (20 mmol; 4 g of ODA dissolved in 50 g of GBL), and the diacid compound represented by formula (II-b-1) is replaced with the diacid compound represented by formula (II-b-2) (30 mmol; 9.9 g). The weight average molecular weight of the polymer of Synthesis Example 4 is 19700, wherein the polymer of Synthesis Example 4 is calculated, a molar ratio of the repeating unit represented by formula (II) to all repeating units in the polymer is 0.30.

Synthesis Example 5: the synthesis steps of the polymer of Synthesis Example 5 are the same as those of Synthesis Example 1, except that the reactants used in Synthesis Example 5 is ODPA (40 mmol; 12.4 g), HEMA (140 mmol; 18.2 g), pyridine (140 mmol; 11.1 g), GBL (200 g), DCC solution (200 mmol; 41.2 g of DCC dissolved in 50 g of GBL) and m-tolidine solution (101 mmol; 21.4 g of m-tolidine dissolved in 200 g of GBL). In Synthesis Example 5, mMEA solution is not used, PMDA is replaced with BPDA (30 mmol; 8.8 g) and the diacid compound represented by formula (II-b-1) is replaced with the diacid compound represented by formula (II-b-2) (30 mmol; 9.9 g). The weight average molecular weight of the polymer of Synthesis Example 5 is 24500, wherein the polymer of Synthesis Example 5 is calculated, a molar ratio of the repeating unit represented by formula (II) to all repeating units in the polymer is 0.30.

Synthesis Example 6: the synthesis steps of the polymer of Synthesis Example 6 are the same as those of Synthesis Example 1, except that the reactants used in Synthesis Example 6 is ODPA (55 mmol; 17.1 g), PMDA (30 mmol; 6.5 g), HEMA (170 mmol; 22.1 g), pyridine (170 mmol; 13.5 g), GBL (200 g), DCC solution (200 mmol; 41.2 g of DCC dissolved in 50 g of GBL) and m-tolidine solution (101 mmol; 21.4 g of m-tolidine dissolved in 200 g of GBL). In Synthesis Example 6, mMEA solution is not used, and the diacid compound represented by formula (II-b-1) is replaced with the diacid compound represented by formula (II-b-3) (15 mmol; 8.8 g). The weight average molecular weight of the polymer of Synthesis Example 6 is 18500, wherein the polymer of Synthesis Example 6 is calculated, a molar ratio of the repeating unit represented by formula (II) to all repeating units in the polymer is 0.15.

The preparation method of the diacid compound represented by formula (II-b-3) is similar to that of the diacid compound represented by formula (II-b-1), expect that 5-aminoisophthalic acid is replaced with bis(4-amino-3-carboxyphenyl) methane.

Synthesis Example 7: the synthesis steps of the polymer of Synthesis Example 7 are the same as those of Synthesis Example 1, except that the reactants used in Synthesis Example 7 is ODPA (40 mmol; 12.4 g), PMDA (30 mmol; 6.5 g), HEMA (140 mmol; 18.2 g), pyridine (140 mmol; 11.1 g), GBL (200 g), DCC solution (200 mmol; 41.2 g of DCC dissolved in 50 g of GBL) and m-tolidine solution (101 mmol; 21.4 g of m-tolidine dissolved in 200 g of GBL). In Synthesis Example 7, mMEA solution is not used, and the diacid compound represented by formula (II-b-1) is replaced with the diacid compound represented by formula (II-a-1) (30 mmol; 8.3 g). The weight average molecular weight of the polymer of Synthesis Example 7 is 31300, wherein the polymer of Synthesis Example 7 is calculated, a molar ratio of the repeating unit represented by formula (II) to all repeating units in the polymer is 0.30.

The preparation method of the diacid compound represented by formula (II-a-1) is similar to that of the diacid compound represented by formula (II-b-1), expect that nadic anhydride is replaced with methylmaleic anhydride.

### Synthesis Comparative Example

Synthesis Comparative Example 1: the synthesis steps of the polymer of Synthesis Comparative Example 1 are the same as those of Synthesis Example 1, except that the reactants used in Synthesis Comparative Example 1 is ODPA (60 mmol; 18.6 g), PMDA (40 mmol; 8.7 g), HEMA (200 mmol; 26 g), pyridine (200 mmol; 15.8 g). GBL (200 g), DCC solution (200 mmol; 41.2 g of DCC dissolved in 50 g of GBL), mMEA solution (10 mmol; 2.8 g of mMEA dissolved in 50 g of GBL) and m-tolidine solution (91 mmol; 19.3 g of m-tolidine dissolved in 150 g of GBL). In Synthesis Comparative Example 1, the diacid compound is not used. The weight average molecular weight of the polymer of Synthesis Comparative Example 1 is 22000.

Synthesis Comparative Example 2: the synthesis steps of the polymer of Synthesis Comparative Example 2 are the same as those of Synthesis Example 1, except that the reactants used in Synthesis Comparative Example 2 is ODPA (40 mmol; 12.4 g), PMDA (30 mmol; 6.5 g), HEMA (140 mmol; 18.2 g), pyridine (140 mmol; 11.1 g), GBL (200 g), DCC solution (200 mmol; 41.2 g of DCC dissolved in 50 g of GBL) and m-tolidine solution (101 mmol; 21.4 g of m-tolidine dissolved in 200 g of GBL). In Synthesis Comparative Example 2, mMEA solution is not used, and the diacid compound represented by formula (II-b-1) is replaced with the diacid compound represented by formula (II-b-4) (30 mmol; 5.0 g). The weight average molecular weight of the polymer of Synthesis Comparative Example 2 is 29700, wherein the polymer of Synthesis Comparative Example 2 is calculated, a molar ratio of the repeating unit represented by formula (II) to all repeating units in the polymer is 0.3.

Synthesis Comparative Example 3: the synthesis steps of the polymer of Synthesis Comparative Example 3 are the same as those of Synthesis Example 1, except that the reactants used in Synthesis Comparative Example 3 is ODPA (95 mmol; 29.5 g), HEMA (190 mmol; 24.7 g), pyridine (190 mmol; 15.0 g), GBL (200 g), the diacid compound represented by formula (II-b-1) (5 mmol; 1.6 g) and DCC solution (200 mmol; 41.2 g of DCC dissolved in 50 g of GBL). In Synthesis Comparative Example 3, PDMA and m-tolidine solution are not used, and mMEA solution is replaced with ODA solution (103 mmol; 20.6 g of ODA dissolved in 200 g of GBL). The weight average molecular weight of the polymer of Synthesis Comparative Example 3 is 37900, wherein the polymer of Synthesis Comparative Example 3 is calculated, a molar ratio of the repeating unit represented by formula (II) to all repeating units in the polymer is 0.05.

Synthesis Comparative Example 4: the synthesis steps of the polymer of Synthesis Comparative Example 4 are the same as those of Synthesis Example 1, except that the reactants used in Synthesis Comparative Example 2 is ODPA (40 mmol; 12.4 g), PMDA (60 mmol; 13.1 g), HEMA (200 mmol; 26.0 g), pyridine (200 mmol; 15.82 g), GBL (150 g), the diacid compound represented by formula (II-b-1) (100 mmol; 32.9 g), DCC solution (400 mmol; 82.4 g of DCC dissolved in 50 g of GBL) and m-tolidine solution (202 mmol; 42.9 g of m-tolidine dissolved in 200 g of GBL). In Synthesis Comparative Example 4, mMEA solution is not used. The weight average molecular weight of the polymer of Synthesis Comparative Example 4 is 20000, wherein the polymer of Synthesis Comparative Example 4 is calculated, a molar ratio of the repeating unit represented by formula (II) to all repeating units in the polymer is 0.5.

The reactants used in the abovementioned Synthesis Examples and Synthesis Comparative Examples are listed in Table 1, and the diacid compound and the chemical structure thereof are listed in Table 2.

TABLE 1

| Abbreviation | Chemical structure and/or chemical name |
|---|---|
| ODPA | 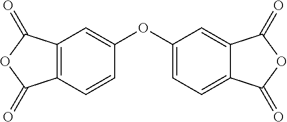 [SMILES: O=C1OC(=O)c2cc(Oc3ccc4c(c3)C(=O)OC4=O)ccc21] |
| | (4,4′-oxydiphthalic anhydride) |
| PMDA | 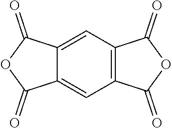 [SMILES: O=c1oc(=O)c2cc3c(=O)oc(=O)c3cc12] |
| | (pyromellitic dianhydride) |
| HEMA | 2-hydroxyethyl methacrylate |
| GBL | gamma-butyrolactone |
| DCC | N,N′-dicyclohexylcarbodiimide |
| mMEA | 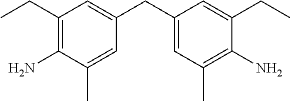 [SMILES: CCc1cc(Cc2cc(C)c(N)c(CC)c2)cc(C)c1N] |
| | (4,4′-methylene-bis(2-methyl-6-ethylaniline)) |
| m-tolidine | 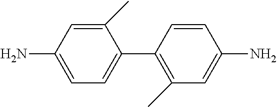 [SMILES: Cc1cc(N)ccc1-c1ccc(N)cc1C] |
| | (2,2′-dimethyl-[1,1′-biphenyl]-4,4′-diamine) |
| ODA | 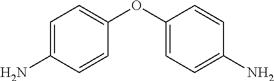 [SMILES: Nc1ccc(Oc2ccc(N)cc2)cc1] |
| | (4,4′-oxydianiline) |
| BPDA | 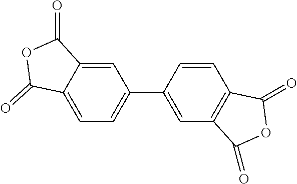 [SMILES: O=C1OC(=O)c2cc(-c3ccc4c(c3)C(=O)OC4=O)ccc21] |
| | (3,3′,4,4′-biphenyltetracarboxylic dianhydride) |

TABLE 2

| | |
|---|---|
| 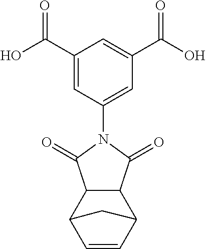 | formula (II-b-1) |
| 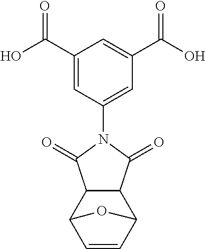 | formula (II-b-2) |
| 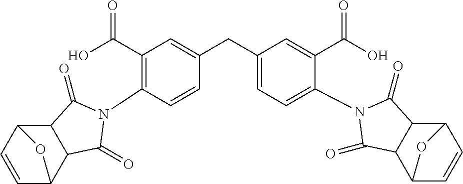 | formula (II-b-3) |
| 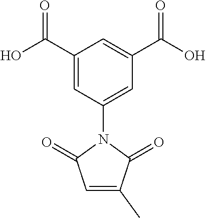 | formula (II-a-1) |
| 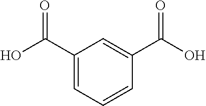 | formula (II-b-4) |

### Example

The curable film of Example 1 to Example 10 are obtained by preparing the polymer of Synthesis Example 1 to Synthesis Example 7 into the photosensitive resin composition according to the component ratio shown in Table 3-1 and Table 3-2, and then curing the photosensitive resin composition.

TABLE 3-1

| | | | Thermal base | | | | Thermal | |
|---|---|---|---|---|---|---|---|---|
| | Polymer | | generator | | Photoinitiator | | crosslinker | |
| | Synthesis | Parts | | Parts | | Parts | | Parts |
| Example | Example | by mass | Type | by mass | Type | by mass | Type | by mass |
| 1 | 1 | 32.7 | DBU-MA | 0.3 | OXE-01 | 1.5 | TAIC | 2.25 |
| 2 | 2 | 32.7 | DBU-MA | 0.3 | OXE-01 | 1.5 | PC74 | 2.25 |
| 3 | 2 | 32.7 | DBU-MA | 0.3 | OXE-01 | 1.5 | TMOMBP | 2.25 |
| 4 | 3 | 32.7 | DBU-MA | 0.3 | OXE-01 | 1.5 | PC74 | 2.25 |
| 5 | 4 | 32.7 | 5002 | 0.3 | OXE-01 | 1.5 | PC74 | 2.25 |
| 6 | 4 | 32.7 | TMG-MA | 0.3 | OXE-01 | 1.5 | PC74 | 2.25 |
| 7 | 4 | 32.7 | DIPEA-MA | 0.3 | OXE-01 | 1.5 | PC74 | 2.25 |
| 8 | 5 | 32.7 | DBU-MA | 0.5 | OXE-01 | 1.5 | PC74 | 2.25 |
| 9 | 6 | 32.7 | DBU-MA | 0.3 | OXE-01 | 1.5 | BMI | 2.25 |
| 10 | 7 | 32.7 | DBU-MA | 0.3 | OXE-01 | 1.5 | BMI | 2.25 |

TABLE 3-2

| | Photo- | | | | | |
|---|---|---|---|---|---|---|
| | polymerizable | | | | Other | |
| | monomer | | Solvent | | additives | Curing |
| | | Parts | | Parts | Parts | condition |
| | | by | | by | by | (° C./ |
| Example | Type | mass | Type | mass | mass | time) |
| 1 | EM2308 | 5.9 | GBL/NEP | 55 | 2.35 | 200/1 hr |
| 2 | EM2308 | 5.9 | GBL/NEP | 55 | 2.35 | 200/1 hr |
| 3 | EM2308 | 5.9 | GBL/NEP | 55 | 2.35 | 200/1 hr |
| 4 | EM2308 | 5.9 | GBL/NEP | 55 | 2.35 | 190/2 hr |
| 5 | EM2308 | 5.9 | GBL/NEP | 55 | 2.35 | 190/2 hr |
| 6 | EM2308 | 5.9 | GBL/NEP | 55 | 2.35 | 190/2 hr |
| 7 | EM2308 | 5.9 | GBL/NEP | 55 | 2.35 | 190/2 hr |
| 8 | EM2308 | 5.9 | GBL/NEP | 55 | 2.15 | 190/2 hr |
| 9 | EM2308 | 5.9 | GBL/NEP | 55 | 2.35 | 170/3 hr |
| 10 | EM2308 | 5.9 | GBL/NEP | 55 | 2.35 | 170/3 hr |

### Comparative Example

The curable film of Comparative Example 1 to Comparative Example 4 are obtained by preparing the polymer of Synthesis Comparative Example 1 to Synthesis Comparative Example 4 into the photosensitive resin composition according to the component ratio shown in Table 4-1 and Table 4-2, and then curing the photosensitive resin composition.

TABLE 4-1

| | | | Thermal base | | | | Thermal | |
|---|---|---|---|---|---|---|---|---|
| | Polymer | | generator | | Photoinitiator | | crosslinker | |
| | Synthesis | Parts | | Parts | | Parts | | Parts |
| Comparative | Comparative | by | | by | | by | | by |
| Example | Example | mass | Type | mass | Type | mass | Type | mass |
| 1 | 1 | 32.7 | DBU-MA | 0.3 | OXE-01 | 1.5 | TAIC | 2.25 |
| 2 | 2 | 32.7 | DBU-MA | 0.3 | OXE-01 | 1.5 | PC74 | 2.25 |
| 3 | 3 | 32.7 | — | — | OXE-01 | 1.5 | PC74 | 2.25 |
| 4 | 3 | 32.7 | — | — | OXE-01 | 1.5 | PC74 | 2.25 |

TABLE 4-2

| | Photo- | | | | Other | |
|---|---|---|---|---|---|---|
| | polymerizable | | | | addi- | |
| | monomer | | Solvent | | tives | Curing |
| | | Parts | | Parts | Parts | condition |
| Comparative | | by | | by | by | (° C./ |
| Example | Type | mass | Type | mass | mass | time) |
| 1 | EM2308 | 5.9 | GBL/NEP | 55 | 2.35 | 200/1 hr |
| 2 | EM2308 | 5.9 | GBL/NEP | 55 | 2.35 | 190/2 hr |
| 3 | EM2308 | 5.9 | GBL/NEP | 55 | 2.35 | 190/2 hr |
| 4 | EM2308 | 5.9 | GBL/NEP | 55 | 2.35 | 190/2 hr |

The component used in the abovementioned Examples and Comparative Examples are listed in Table 5.

TABLE 5

| | |
|---|---|
| Abbrevia- | |
| tion | Chemical structure and/or chemical name |

Thermal base generator

| | | |
|---|---|---|
| DBU-MA | 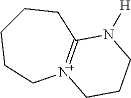 [SMILES: C1CCC2=[N+](CC1)CCCN2] | 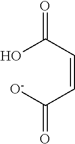 |
| 5002 | 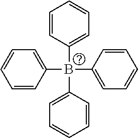 | 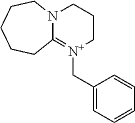 [SMILES: c1ccc(C[N+]2=C3CCCCCN3CCC2)cc1] |
| TMG-MA | 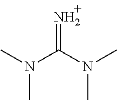 | 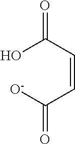 |
| DIPEA- MA | 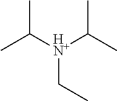 | 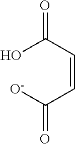 |

Photoinitiator

| | |
|---|---|
| OXE-01 | 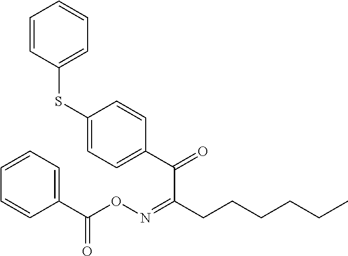 [SMILES: CCCCCC/C(=N/OC(=O)c1ccccc1)C(=O)c1ccc(Sc2ccccc2)cc1] |
| | photoinitiator produced by BASF with product number |
| | OXE-01 |

Thermal crosslinker

| | |
|---|---|
| TAIC | 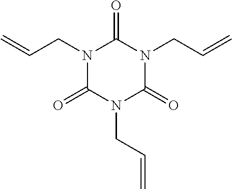 [SMILES: C=CCn1c(=O)n(CC=C)c(=O)n(CC=C)c1=O] |
| PC74 | 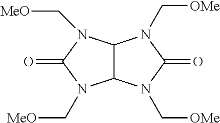 [SMILES: COCN1C(=O)N(COC)C2C1N(COC)C(=O)N2COC] |
| TMOMBP | 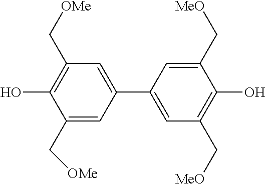 [SMILES: COCc1cc(-c2cc(COC)c(O)c(COC)c2)cc(COC)c1O] |
| BMI | 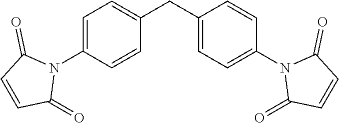 [SMILES: O=C1C=CC(=O)N1c1ccc(Cc2ccc(N3C(=O)C=CC3=O)cc2)cc1] |

Photopolymerizable monomer

| | |
|---|---|
| EM2308 | 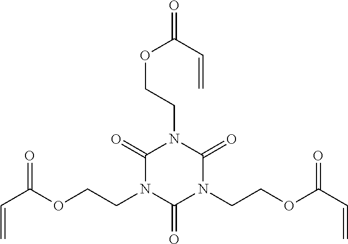 [SMILES: C=CC(=O)OCCn1c(=O)n(CCOC(=O)C=C)c(=O)n(CCOC(=O)C=C)c1=O] |
| | photopolymerizable monomer produced by ETERNAL |
| | MATERIALS CO., LTD with product number EM2308 |

Solvent

| | |
|---|---|
| NEP | N-ethyl pyrrolidone |

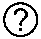

It should be noted that the curable film of the abovementioned Examples and Comparative Examples are produced by using the following steps. The prepared photosensitive resin composition is evenly coated on the glass substrate or the copper substrate by using the spin coater, and then dried by pre-baking (80° C. to 120° C. for 1 to 5 minutes) to form the pre-baked film with the thickness of 3 μm to 20 μm. Next, the stepper is used to expose the pre-baked film with UV-light (wavelength is 300 nm to 500 nm and exposure dose is 200 mj to 1000 mj) directly or through the photomask. After the exposure, the developer (cyclopentanone) is used to dissolve away the unexposed areas to obtain the resin film with the patterned. Then, the resin film is placed in the deoxygenating oven for curing, wherein the curing temperature is 170° C. to 200° C. and the curing time is 1 to 3 hours to obtain the curable film.

### <Property Test of Curable Film>

The cyclization rate, the chemical resistance and the thermal property of the curable film of Example 1 to Example 10 and Comparative Example 1 to Comparative Example 4 are tested below.

In the cyclization rate test, the curable film is detected by the fourier transform-infrared spectroscope (FT-IR), and the cyclization rate of the curable film is calculated using the following formula:

$$The cyclization rate = [ ( 1 - T {\%}_{1377} ) / ( 1 - T {\%}_{1488} ) ] {/ [ ( 1 - T {\%}_{1377} ) / ( 1 - T {\%}_{1488} ) ]}_{( @ 350 ) ° C} ;$$

wherein T %₁₃₇₇ and T %₁₄₈₈ are the transmittances of FT-IR at the wavelengths of 1377 nm and 1488 nm, respectively.

In the chemical resistance test, the curable film is immersed in the SPR920 solution (the chemical solution produced by KANTO-PPC Inc., consisting of teteramethylammonium hydroxide (TMAH), dimethyl sulfoxide (DMSO) and water) at 50° C. and the dissolution rate of the curable film is detected.

In the thermal property test, the decomposition temperature (Td_{5%}) of the curable film is detected by the thermogravimetric analyzer (TGA). The testing instrument of TGA is TA instrument Q-500, and the test condition is under the nitrogen atmosphere with the heating rate of 10° C./min from 40° C. to 500° C. Furthermore, the storage modulus (E′) and the glass transition temperature (T_{g}) of the curable film are detected by the dynamic mechanical analyzer (DMA). The testing instrument of DMA is Perkin Elmer DMA800, and the test condition is under the frequency of 1 Hz, the deformation of 0.02 mm with the heating rate of 5° C./min from 40° C. to 300° C.

The property test results of the curable film of Example 1 to Example 10 and Comparative Example 1 to Comparative Example 4 are listed in Table 6.

TABLE 6

| | Cyclization | Chemical | | E′ | |
|---|---|---|---|---|---|
| | rate | resistance | Td_{5%} | (245° C.) | T_{g} |
| Example 1 | A | B | A | B | B |
| Example 2 | A | B | A | A | A |
| Example 3 | A | B | A | A | A |
| Example 4 | A | A | A | A | A |
| Example 5 | A | A | A | A | A |
| Example 6 | A | A | A | A | A |
| Example 7 | A | A | A | A | A |
| Example 8 | A | A | A+ | A | A |
| Example 9 | B | A | B | A | B |
| Example 10 | B | A | B | A | B |
| Comparative | A | B | A | D | D |
| Example 1 | | | | | |
| Comparative | A | B | B | D | D |
| Example 2 | | | | | |
| Comparative | D | D | E | D | D |
| Example 3 | | | | | |
| Comparative | D | D | E | A | A |
| Example 4 | | | | | |

Evaluation standard of cyclization rate: A is more than 90%; B is more than 80% and less than 90%; C is more than 70% and less than 80%; D is more than 60% and less than 70%.

Evaluation standard of chemical resistance: A is dissolution rate less than 30 nm/min; B is dissolution rate more than 30 nm/min and less than 60 nm/min; C is dissolution rate more than 60 nm/min and less than 100 nm/min; D is dissolution rate more than 100 nm/min.

Evaluation standard of Td_{5%}: A+ is more than 350° C.; A is more than 340° C. and less than 350° C.; B is more than 330° C. and less than 340° C.; C is more than 320° C. and less than 330° C.; D is more than 310° C. and less than 320° C.; E is less than 310° C.

Evaluation standard of E′: A is more than 0.4 GPa; B is more than 0.2 GPa and less than 0.4 GPa; C is more than 0.1 GPa and less than 0.2 GPa; D is less than 0.1 GPa.

Evaluation standard of T_{g}: A is more than 260° C.; B is more than 250° C. and less than 260° C.; C is more than 240° C. and less than 250° C.; D is less than 240° C.

As shown in Table 6, it can be known that compared to the curable film of Comparative Example 1 to Comparative Example 4, the curable film of the present disclosure can have the higher cyclization rate, decomposition temperature, storage modulus, glass transition temperature and the better chemical resistance simultaneously. Furthermore, as shown in Table 3-2 and Table 4-2, it can be known that the curable film of the present disclosure can have the abovementioned excellent material properties at the relatively lower curing temperature (less than or equal to 200° C.).

In conclusion, the photosensitive resin composition of the present disclosure has the specific structure, which is favorable for the polymer rearrangement and crosslinking reaction, and increasing the crosslink density of the molecular chain of the polymer, so that maintains the high glass transition temperature at the low curing temperature (≤200° C.) to improve the thermal and mechanical properties of the product after curing. On the other hand, the high cyclization rate and the excellent chemical resistance are maintained at the low curing temperature (≤200° C.) by adding the thermal base generator. In addition, the photosensitivity is provided by the photosensitive crosslinking group in the polymer, so that can be patterned through the exposure and development. Thus, the photosensitive resin composition can have the properties of the insulating material and the photoresist material simultaneously, which is favorable for reducing the process steps, costs and improving the yield.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A photosensitive resin composition, comprising:
a polymer, which has a plurality of repeating units represented by formula (I) and a plurality of repeating units represented by formula (II): 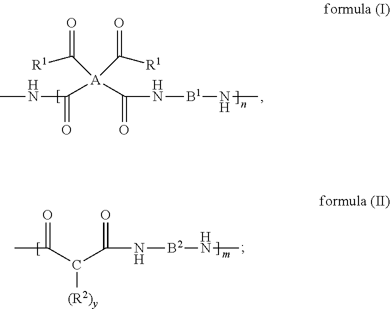
wherein A is a tetravalent organic group of 6 to 40 carbon atoms, B¹ and B² are each independently a divalent organic group of 6 to 40 carbon atoms, C is a trivalent organic group to a hexavalent organic group of 6 to 40 carbon atoms, R¹ is a photosensitive crosslinking group, and R² has a structure represented by formula (II-a) or formula (II-b): 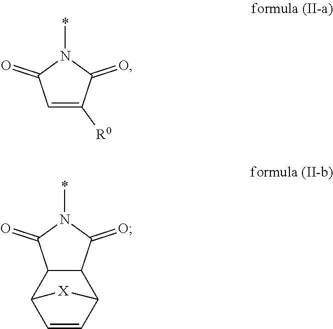
wherein R⁰ is a hydrogen atom or a methyl group, and X is a methylene group, an oxygen atom or a sulfur atom;
wherein n is an integer greater than or equal to 1, m is an integer greater than or equal to 1, and y is an integer from 1 to 3;
wherein when X is the methylene group, the following condition is satisfied:
0.1≤a molar ratio of the repeating units represented by formula (II) to all repeating units of the polymer≤0.4.

2. The photosensitive resin composition of claim 1, wherein A is the tetravalent organic group comprising 1 to 4 benzene rings, B¹ and B² are each independently the divalent organic group comprising 1 to 4 benzene rings, and C is the trivalent organic group to the hexavalent organic group comprising 1 to 4 benzene rings.

3. The photosensitive resin composition of claim 2, wherein the benzene rings of at least one of A, B¹, B² and C has at least one linking group therebetween, and the at least one linking group is a divalent organic group of 1 to 6 carbon atoms.

4. The photosensitive resin composition of claim 3, wherein the at least one linking group comprises at least one selected from a group consisting of an oxygen atom, a nitrogen atom, a sulfur atom, an alkenyl group, an alkynyl group, an ester group, an ether group, and a ketone group.

5. The photosensitive resin composition of claim 1, wherein R¹ has a structure represented by formula (III): 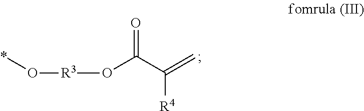
wherein R³ is an alkylene group of 1 to 8 carbon atoms, and R⁴ is a hydrogen atom or an alkyl group of 1 to 3 carbon atoms.

6. The photosensitive resin composition of claim 1, wherein n is an integer from 1 to 150, and m is an integer from 1 to 150.

7. The photosensitive resin composition of claim 1, further comprising a thermal crosslinking agent.

8. The photosensitive resin composition of claim 7, wherein the thermal crosslinking agent has a thermally reactive functional group, and the thermally reactive functional group is at least one selected from a group consisting of a hydroxymethyl group, an alkoxymethyl group, an oxiranyl group, an isocyanate group, a bismaleimide group, an alkenyl group and an alkynyl group.

9. The photosensitive resin composition of claim 1, further comprising at least one of a photoinitiator and a multifunctional acrylic photocrosslinker.

10. A photosensitive resin composition, comprising:
a thermal base generator; and
a polymer, which has a plurality of repeating units represented by formula (I) and a plurality of repeating units represented by formula (II): 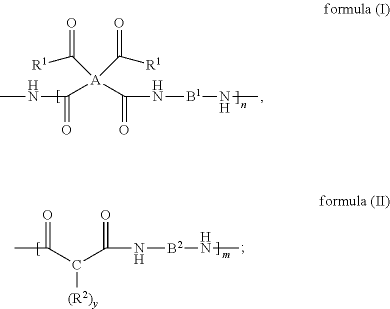
wherein A is a tetravalent organic group of 6 to 40 carbon atoms, B¹ and B² are each independently a divalent organic group of 6 to 40 carbon atoms, C is a trivalent organic group to a hexavalent organic group of 6 to 40 carbon atoms, R¹ is a photosensitive crosslinking group, and R² has a structure represented by formula (II-a) or formula (II-b): 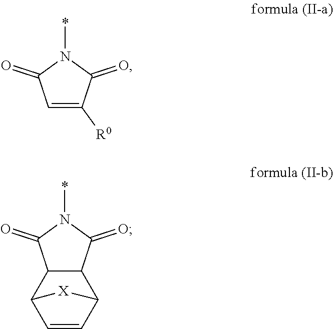
wherein R⁰ is a hydrogen atom or a methyl group, and X is a methylene group, an oxygen atom or a sulfur atom;
wherein n is an integer greater than or equal to 1, m is an integer greater than or equal to 1, and y is an integer from 1 to 3.

11. The photosensitive resin composition of claim 10, wherein R¹ has a structure represented by formula (III): 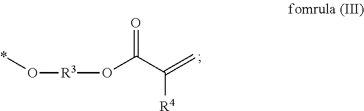
wherein R³ is an alkylene group of 1 to 8 carbon atoms, and R⁴ is a hydrogen atom or an alkyl group of 1 to 3 carbon atoms.

12. The photosensitive resin composition of claim 10, wherein n is an integer from 1 to 150, and m is an integer from 1 to 150.

13. The photosensitive resin composition of claim 10, wherein the thermal base generator has at least one of a structure represented by formula (IV) and a structure represented by formula (V): 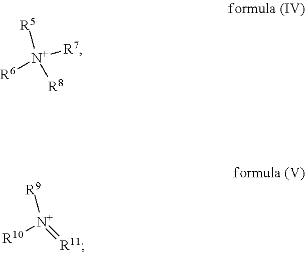
wherein R⁵, R⁶, R⁷, R⁸, R⁹ and R¹⁰ are each independently a hydrogen atom, an aromatic ring group or an alkyl group, and R¹¹ is an alkylene group.

14. The photosensitive resin composition of claim 13, wherein at least one of R⁵, R⁶, R⁷, R⁸, R⁹, R¹⁰ and R¹¹ is substituted by at least one selected from a group consisting of an oxygen atom, a nitrogen atom, a sulfur atom, an alkenyl group, an alkynyl group, an ether group and a ketone group.

15. The photosensitive resin composition of claim 10, wherein the thermal base generator has at least one of a structure represented by formula (IV) and a structure represented by formula (V): 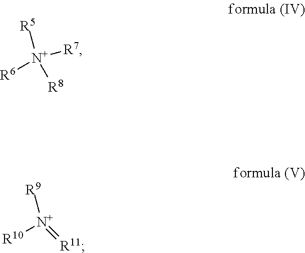
wherein at least one of R⁵ and R⁶, R⁷ and R⁸, R⁹ and R¹⁰, R⁹ and R¹¹ is bonded to form a cyclic structure.

16. The photosensitive resin composition of claim 10, wherein the polymer is a copolymer.

17. A curable film, which is formed by curing the photosensitive resin composition of claim 1 or claim 10;
wherein the repeating units represented by formula (I) in the photosensitive resin composition undergo a cyclization reaction to form a plurality of repeating units represented by formula (I-1):

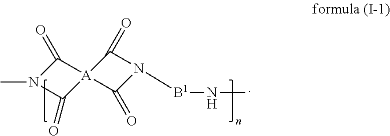

18. The curable film of claim 17, wherein a cyclization rate of the curable film is greater than 80%.
